(19) United States
(12) Patent Application Publication
(10) Pub. No.: US 2025/0046607 A1
(43) Pub. Date: Feb. 6, 2025

(54) SUBSTRATE PROCESSING METHOD

(71) Applicant: Tokyo Electron Limited, Tokyo (JP)

(72) Inventors: Takashi FUSE, Yamanashi (JP); Kazuya KATO, Yamanashi (JP); Shuji AZUMO, Yamanashi (JP)

(21) Appl. No.: 18/836,133

(22) PCT Filed: Feb. 2, 2023
(86) PCT No.: PCT/JP2023/003339

§ 371 Date: Aug. 6, 2024

(30) Foreign Application Priority Data
Feb. 10, 2022 (JP) 2022-019518

(51) Int. Cl. H01L 21/02

(52) U.S. Cl. CPC H01L 21/02304; H01L 21/02211; H01L 21/0228; H01L 21/02178

(57) ABSTRACT

A substrate processing method is provided that forms a target film on a first material layer of a substrate that includes the first material layer and a second material layer. The substrate processing method includes forming a first organic film on the first material layer of the substrate including the first material layer and the second material layer different from the first material layer, supplying a process gas including a raw material of a target film to form a first target film on the second material layer, and to allow the an outermost surface of the first organic film to react with the process gas to form an adsorption layer, forming a second organic film on the adsorption layer, and forming a second target film on the first target film.

### TECHNICAL FIELD

The present disclosure relates to substrate processing method.

### BACKGROUND ART

Patent Literature 1 discloses an electrophotographic photoconductor including an electrode layer and a photoconductive layer, where a self-assembled film is formed on the photoconductive layer side of the electrode layer, and the self-assembled film is formed of organic silane alkoxides, organic silane halides, organic disilazanes, carboxylic acids, hydroxamic acids, phosphonic acids, thiols, sulfides, or the like, such as, a self-assembled film formed of a monolayer of 3-mercaptopropylsiloxy groups on an aluminum mylar film.

### CITATION LIST

### Patent Literature

Patent Literature 1: Japanese Unexamined Patent Application Publication No. 09-292731

### SUMMARY OF THE INVENTION

### Problem to be Solved by the Invention

One aspect of the present disclosure provides a substrate processing method that forms a target film on a first material layer of a substrate that includes the first material layer and a second material layer.

### Means for Solving the Problem

A substrate processing method according to one aspect of the present disclosure includes: forming a first organic film on a first material layer of a substrate, where the substrate includes the first material layer and a second material layer different from the first material layer; supplying a process gas including a raw material of a target film to form a first target film on the second material layer, and to allow an outermost surface of the first organic film to react with the process gas to form an adsorption layer; forming a second organic film on the adsorption layer; forming a second target film on the first target film.

### Advantageous Effects of Invention

According to one aspect of the present disclosure, it is possible to provide a substrate processing method that forms a target film on a first material layer of a substrate that includes the first material layer and a second material layer.

### BRIEF DESCRIPTION OF THE DRAWINGS

FIG. 1 is a schematic cross-sectional view illustrating one example of the film-forming apparatus of the present embodiment.

FIG. 2 is a flowchart illustrating one example of a formation method of an insulating film.

FIG. 3 is a flowchart illustrating one example of a process of step S104.

FIG. 4 is a flowchart illustrating one example of a process of step S107.

FIG. 5A is one example of a schematic cross-sectional view of a substrate.

FIG. 5B is one example of a schematic cross-sectional view of the substrate.

FIG. 5C is one example of a schematic cross-sectional view of the substrate.

FIG. 5D is one example of a schematic cross-sectional view of the substrate.

FIG. 5E is one example of a schematic cross-sectional view of the substrate.

FIG. 5F is one example of a schematic cross-sectional view of the substrate.

FIG. 5G is one example of a schematic cross-sectional view of the substrate.

FIG. 5H is one example of a schematic cross-sectional view of the substrate.

FIG. 5I is one example of a schematic cross-sectional view of the substrate.

FIG. 6A is one example of a graph explaining a thickness of an organic film.

FIG. 6B is one example of a graph explaining a thickness of the organic film.

FIG. 6C is one example of a graph explaining a thickness of the organic film.

FIG. 7A is one example of a diagram explaining the substrate processing method of the present embodiment in comparison with a referential example.

FIG. 7B is one example of a diagram explaining the substrate processing method of the present embodiment in comparison with the referential example.

FIG. 7C is one example of a diagram explaining the substrate processing method of the present embodiment in comparison with the referential example.

FIG. 7D is one example of a diagram explaining the substrate processing method of the present embodiment in comparison with the referential example.

### DETAILED DESCRIPTION OF THE INVENTION

Hereinafter, non-limiting embodiments of the present disclosure will be described with reference to the attached drawings. Throughout the attached drawings, the same or corresponding members or parts are designated by the same or corresponding reference symbols, and redundant description thereof will be omitted.

### [Film-Forming Apparatus]

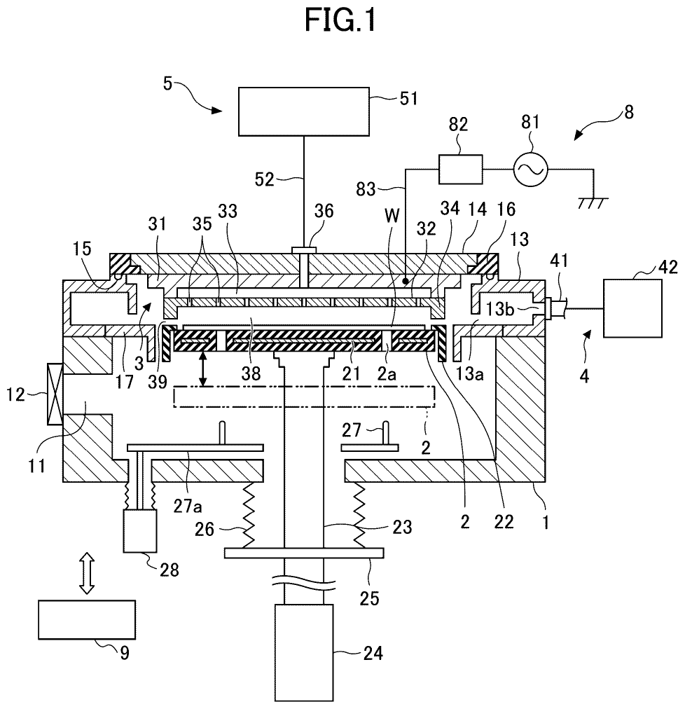

With reference to FIG. 1, one example of the film-forming apparatus of the present embodiment will be explained. The film-forming apparatus includes a process chamber 1, a stage 2, a showerhead 3, exhaust 4, a gas supply 5, an RF-power supply 8, and a controller 9, and the like.

The process chamber 1 is formed of a metal, such as aluminum or the like, and has substantially a cylindrical shape. The process chamber 1 houses a wafer W that is an example of the substrate. A loading port 11 through which the wafer W is transported in and out is formed in a side wall of the process chamber 1. The loading port 11 is opened and closed by a gate valve 12. An annular exhaust duct 13 having a rectangular cross-sectional shape is disposed above a main body of the process chamber 1. A slit 13a is formed along an inner circumferential surface of the exhaust duct 13. An exhaust port 13b is formed in an outer wall of the exhaust duct 13. A ceiling wall 14 is disposed on an upper surface of the exhaust duct 13 to cover an upper opening of the process chamber 1 via an insulating member 16. A space between the exhaust duct 13 and the insulating member 16 airtightly sealed by a seal ring 15. A partition member 17 partitions the interior of the process chamber 1 into an upper side and a lower side when the stage 2 (and a cover member 22) is lifted to a below-described processing position.

The stage 2 horizontally supports the wafer W in the process chamber 1. The stage 2 is formed in a disc shape having a size corresponding to the wafer W, and is supported by a support member 23. The stage 2 is formed of a ceramic material, such as AlN or the like, or a metal material, such as aluminum, a nickel alloy, or the like, and a heater 21 for heating the wafer W is embedded in the stage 2. A heater power source (not illustrated) supplies electricity to the heater 21 to generate heat. The temperature of the wafer W is regulated at a set temperature by controlling an output of the heater 21 according to a temperature signal of a thermocouple (not illustrated) disposed in the vicinity of an upper surface of the stage 2. A cover member 22 formed of a ceramic, such as alumina or the like, is disposed above the stage 2 to cover an outer peripheral region of the upper surface of the stage 2, and a side surface of the stage 2.

A support member 23 is disposed on a bottom surface of the stage 2, and supports the stage 2. The support member 23 extends from a center of the bottom surface of the stage 2 to the bottom side of the process chamber 1 through a hole formed in a bottom wall of the process chamber 1, and a lower end of the support member 23 is coupled to the lifting mechanism 24. The stage 2 is lifted up and lowered down between the processing position and the loading position below the processing position illustrated in FIG. 1 by the lifting mechanism 24 via the support member 23. The loading position is indicated with a double-dashed chain line, and is a position where the wafer W can be transported in and out. A flange 25 is attached to the support member 23 below the process chamber 1. A bellows 26 is disposed between the bottom surface of the process chamber 1 and the flange 25. The bellows 26 partitions the inner atmosphere of the process chamber 1 off from the outside air, and expands and contracts according to the lifting and lowering movements of the stage 2.

In the vicinity of the bottom surface of the process chamber 1, three (only two are illustrated) wafer support pins 27 are disposed to be projected upward from a lifting plate 27a. The wafer support pins 27 are lifted up and lowered down with the lifting plate 27a by a lifting mechanism 28 disposed below the process chamber 1. The wafer support pins 27 are inserted through holes formed in the stage 2 in the loading position to be projected from and pulled down from the upper surface of the stage 2. By lifting and lowering the wafer support pins 27, the wafer W is transported between a transfer mechanism (not illustrated) and the stage 2.

The showerhead 3 is configured to supply a process gas into the process chamber 1 in the form of shower. The showerhead 3 is formed of a metal, disposed to face the stage 2, and has substantially the same diameter as a diameter of the stage 2. The showerhead 3 includes a main body 31 and a shower plate 32. The main body 31 is fixed onto the ceiling wall 14 of the process chamber 1. The shower plate 32 is connected to the bottom of the main body 31. A gas diffusion space 33 is created between the main body 31 and the shower plate 32. A gas inlet hole 36 is provided to the gas diffusion space 33, where the gas inlet hole 36 penetrates through the ceiling wall 14 of the process chamber 1 and a center of the main body 31. An annular projection 34 projecting downward is formed on the peripheral edge of the shower plate 32. Gas discharge holes 35 are formed in a flat portion located on an inner side of the annular projection 34. In a state where the stage 2 is in the processing position, a processing space 38 is created between the stage 2 and the shower plate 32, and an annular gap 39 are formed by bring the upper surface of the cover member 22 close to the annular projection 34.

The exhaust 4 exhausts the inner atmosphere of the process chamber 1. The exhaust 4 includes an exhaust pipe 41 connected to an exhaust port 13b, and an exhaust mechanism 42 connected to the exhaust pipe 41. The exhaust mechanism 42 includes a vacuum pump, a pressure control valve, and the like. During processing, a gas inside the process chamber 1 passes through the slit 13a to reach the exhaust duct 13, and the gas is exhausted from the exhaust duct 13 by the exhaust mechanism 42 through the exhaust pipe 41.

The gas supply 5 is configured to supply various process gases to the showerhead 3. The gas supply 5 includes a gas source 51 and a gas line 52. The gas source 51 includes, for example, supply sources of various process gases, a mass flow controller, and a valve (all of which are not illustrated). Various process gases are introduced into the gas diffusion space 33 from the gas source 51 via the gas line 52 and the gas inlet hole 36.

Moreover, the film-forming apparatus is a capacitively coupled plasma apparatus, in which the stage 2 functions as a lower electrode and the showerhead 3 functions as an upper electrode. The stage 2 is grounded via a capacitor (not illustrated). However, the stage 2 may be, for example, grounded without the capacitor, or grounded via a circuit in which a capacitor and a coil are combined. The showerhead 3 is coupled to the RF-power supply 8.

The RF-power supply 8 supplies high-frequency power (may be referred to as “RF power” hereinafter) to the showerhead 3. The RF-power supply 8 includes an RF power source 81, a impedance matching device 82, and a feeder 83. The RF power source 81 is a power source that generates RF power. RF power has frequencies suitable for generation of plasma. The frequencies of the RF power are, for example, in a range of 450 kHz in the low frequency band to 2.45 GHz in the microwave band. The RF power source 81 is coupled to the main body 31 of the showerhead 3 via the impedance matching device 82 and the feeder 83. The impedance matching device 82 includes a circuit for matching load impedance with the internal impedance of the RF power source 81. Although the RF-power supply 8 is explained as supplying RF power to the showerhead 3 serving as the upper electrode, an embodiment of the RF-power supply 8 is not limited to the above embodiment. The RF-power supply 8 may be configured to supply RF power to the stage 2 serving as the lower electrode.

The controller 9 is, for example, a computer, and includes a central processing unit (CPU), a random access memory (RAM), a read only memory (ROM), an auxiliary storage device, and the like. The controller 9 causes the CPU to execute programs stored in the ROM or auxiliary storage device, thereby controlling operation of the film-forming apparatus. The controller 9 may be disposed inside or outside the film-forming apparatus. When the controller 9 is disposed outside the film-forming apparatus, the controller 9 can control the film-forming apparatus by a communication device, such as a wired communication device, a wireless communication device, or the like.

### [Formation Method of Silicon Nitride Film]

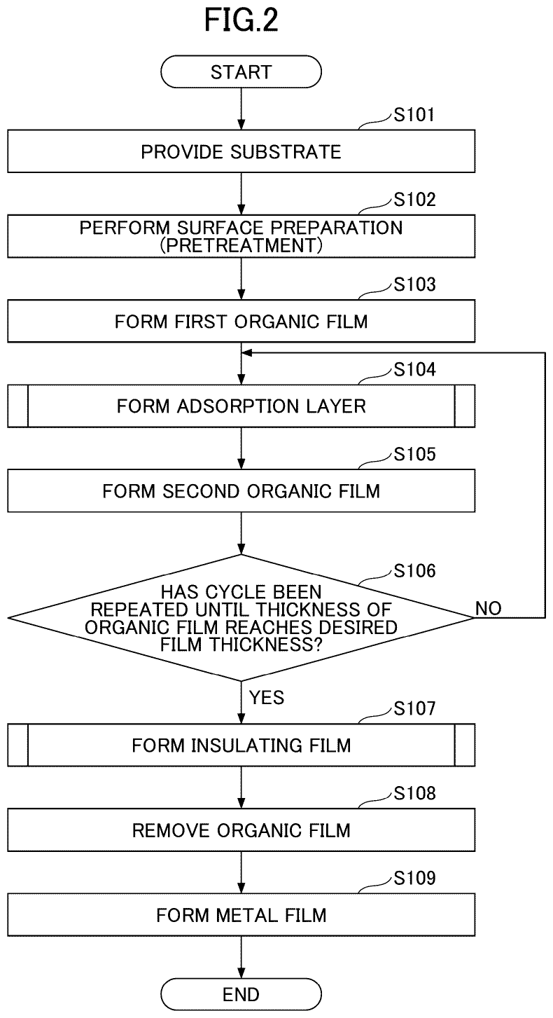

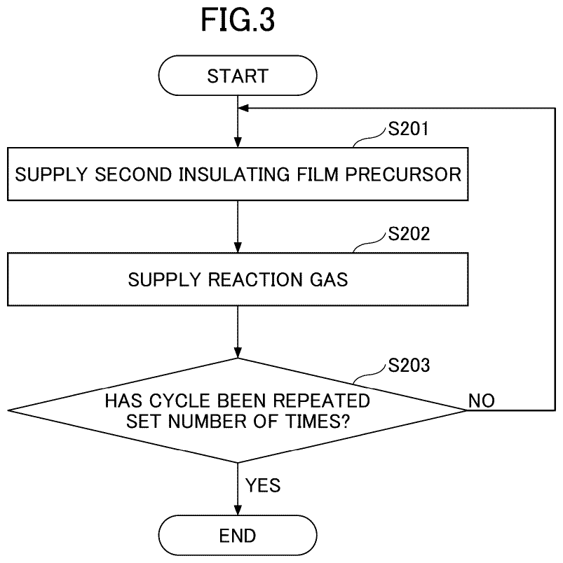

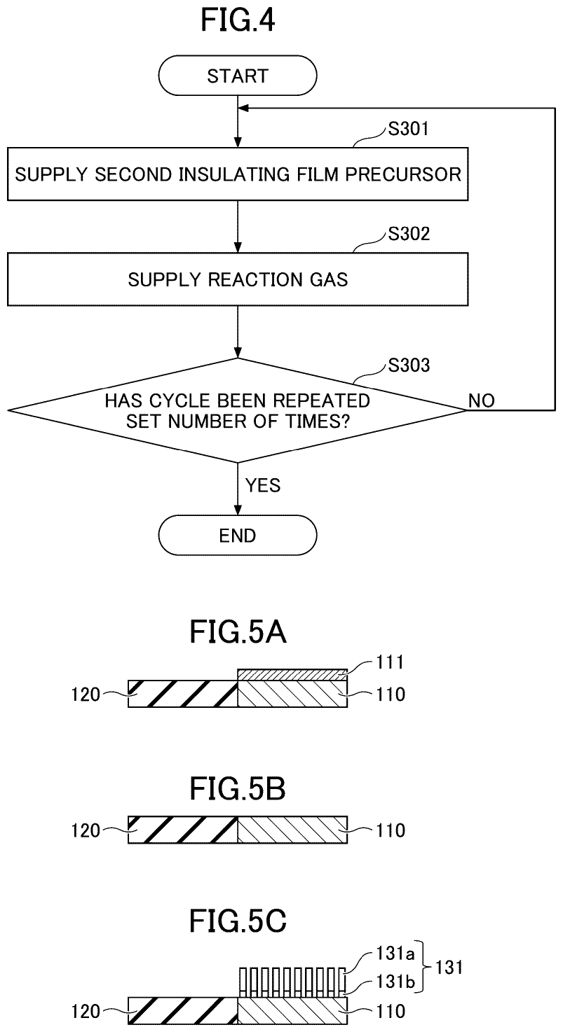

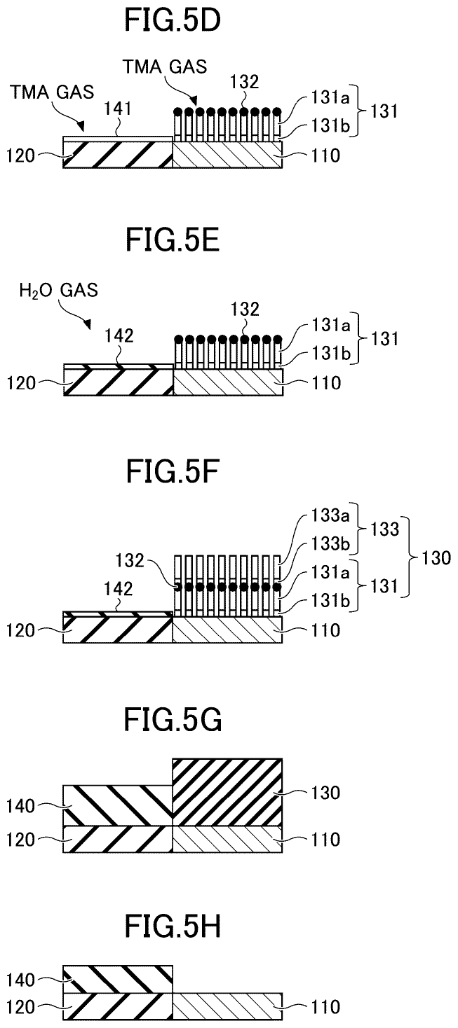

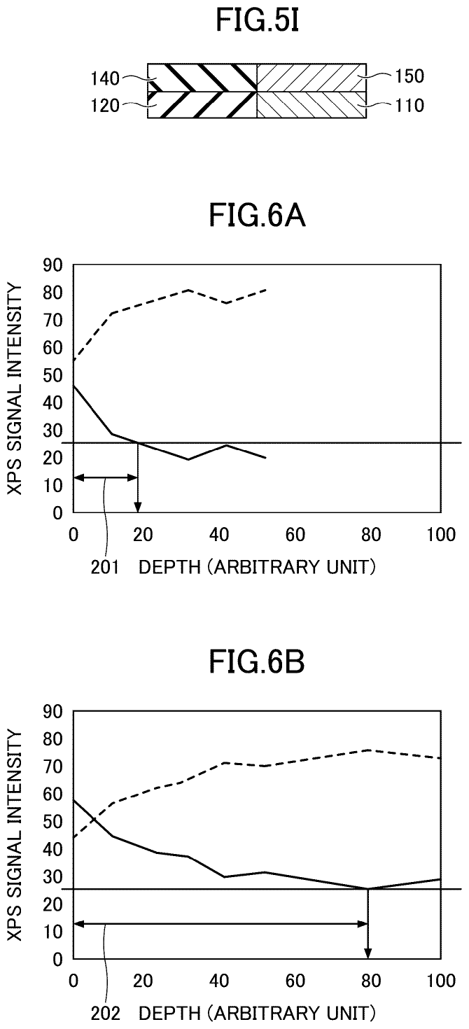

With reference to FIG. 2, a formation method of an insulating film will be explained using FIG. 2 through FIG. 5I. FIG. 2 is a flowchart illustrating one example of the formation method of the insulating film. FIG. 3 is a flowchart illustrating one example of a process of step S104. FIG. 4 is a flowchart illustrating one example of a process of step S107. Each of FIGS. 5A to 5I is one example of a schematic cross-sectional view of a substrate.

At step 3101, the controller 9 is configured to provide a wafer W. As illustrated in FIG. 5A, the wafer W includes a metal film 110 and a first insulating film 120 serving as an insulating film. For example, the metal film 110 is an electroconductive film, such as a Cu film, a Ru film, or the like. Moreover, a native oxide film 111 is formed on a surface of the metal film 110. The controller 9 controls the lifting mechanism 24 to lower the stage 2 to the loading position. In this state, the gate valve 12 is opened. Subsequently, a wafer W is transported into the process chamber 1 by a transfer arm (not illustrated) through the loading port 11, and is mounted on the stage 2 heated at a set temperature (e.g., 600° C. or lower) by the heater 21. Subsequently, the controller 9 controls the lifting mechanism 24 to lift the stage 2 up to the processing position, and the inner atmosphere of the process chamber 1 is vacuumed at a set degree of vacuum by an exhaust mechanism 42.

At step S102, the controller 9 is configured to perform surface preparation (pretreatment) for forming a below-described first organic film 131 or forming a below-described first target film 142. The surface preparation of step S102 includes, for example, removal of a native oxide film formed on the surface of the wafer W or removal of contaminants. Moreover, the surface preparation includes, for example, a process of modifying the surface of the wafer W, from which the native oxide film formed on the wafer W or the contaminants are removed. For example, at step S102, the controller 9 is configured to perform a process of removing the native oxide film 111 of the wafer W. For example, the controller 9 is configured to supply a reducing gas (e.g., hydrogen, alcohol, etc.) into the process chamber 1, and to heat the wafer W, for example, at 200° C., thereby removing the native oxide film 111 formed on the surface of the metal film 110. Thus, as illustrated in FIG. 5B, the native oxide film 111 is removed from the surface of the metal film 110.

At step S103, the controller 9 is configured to form a first organic film 131. For example, the controller 9 is configured to supply an organic molecule gas into the process chamber 1. Each organic molecule includes a straight chain 131a and a reactive functional group 131b reactive with a base (metal film 110). The straight chain 131a is a straight chain including C (carbon) and F (halogen). The reactive functional group 131b is a functional group that is selectively adsorbed on the metal film 110. The functional group includes any of thiol, carboxylic acid, silane coupling, or the like. As the organic molecules, organic molecules including carboxylic acid (—COOH), such as fluoroalkyl carboxylic acid (heptafluorobutyric acid) or the like, can be used. Thus, as illustrated in FIG. 5C, the reactive functional groups 131b are adsorbed on the surface of the metal film 110 to form a self-assembled monolayer (SAM) as an organic film, which constitutes a first organic film 131 having a thickness according to a length of the straight chain 131a.

Conversely, the reactive functional groups 131b are inhibited from being adsorbed onto the first insulating film 120. Therefore, the first organic film 131 is selectively formed on the metal film 110.

As a length of each straight chain 131a increases, a thickness of the first organic film 131 becomes thicker. However, a molecular weight of each organic molecule is also increased so that a temperature (boiling point, vaporization temperature) at which the organic molecules are transformed into a gas becomes high. Therefore, a thickness of the first organic film 131 is restricted.

A process of step S104 will be further explained with reference to FIG. 3. At step S104 (S201), the controller 9 is configured to supply a precursor of a second insulating film 140. Here, a trimethyl aluminum (TMA) gas is supplied as the precursor of the second insulating film 140. Thus, as illustrated in FIG. 5D, TMA is adsorbed onto a surface of the first insulating film 120, thereby forming an adsorption layer 141. Moreover, TMA is adsorbed on a surface of the first organic film 131, thereby forming an adsorption layer 132. The adsorption layer 132 is formed as follows. As TMA is supplied, CH₃ in each TMA molecule causes a substitution reaction with fluorine of a CFX chain of each straight chain 131a in the organic film 131 to form AL molecules each including ALF on the surface of the first organic film 131. Thus, ALF groups (adsorption layer) 132 are attached at terminals (outermost surface) of the straight chains 131a of the organic molecules.

Next, at step S104 (S202), the controller 9 is configured to supply a reaction gas that reacts with the precursor of the second insulating film 140. Here, a H₂O gas is supplied as the reaction gas for the second insulating film 140. Thus, as illustrated in FIG. 5E, TMA adsorbed on the surface of the first insulating film 120 is reacted to form a first target film 142. Conversely, the AlF groups (adsorption layer) 132 are hardly reacted.

Next, at step S104 (S203), the controller 9 determines whether or not a cycle is repeated a set number of times, where the cycle includes the processes of step S201 and step 3202. In the case where the cycle has not been repeated the set number of times (S203, NO), the controller 9 is configured to return the process back to step 3201. In the case where the cycle has been repeated the set number of times (S203, YES), the controller 9 is configured to end the process of step 3104, and to proceed with step 3105 (see FIG. 2).

As illustrated in FIG. 3, when determining that the process of supplying the precursor of the second insulating film 140 (3201) and the process of supplying the reaction gas for the second insulating film 140 (3202) as a cycle, the cycle is repeated two or more times (3203) so that AlF groups (adsorption layer) 132 are densified.

Moreover, when an adsorption layer 132 is formed at step 3104, a main aim is to achieve the reaction and adsorption between terminal groups of molecules of the organic film and TMA, thus duration for supplying the reaction gas in the process of supplying the reaction gas (S202) may be shorter than duration for supplying the precursor in the process of supplying the precursor (3201). Moreover, the process of supplying the reaction gas (3202) may be omitted at step 3104. Specifically, the process of supplying the precursor (3201) may be performed within a set period of time, or may be intermittently performed at step 3104. Thus, the reaction and adsorption between terminal groups of molecules of the organic film and TMA are facilitated.

At step S105, the controller 9 is configured to form a second organic film 133. For example, the controller 9 is configured to supply an organic molecule gas into the process chamber 1. Each organic molecule includes a straight chain 133a and a reactive functional group 133b reactive with an AlF group (adsorption layer) 132. The straight chain 133a is a straight chain including C (carbon) and F (halogen). The reactive functional group 133b is a functional group (e.g., carboxylic acid (—COOH)) that is selectively adsorbed on an AlF group. As the organic molecules, organic molecules including carboxylic acid (—COOH), such as fluoroalkyl carboxylic acid (heptafluorobutyric acid) or the like, can be used. Thus, as illustrated in FIG. 5F, a second organic film 133 can be selectively formed on the first organic film 131. Moreover, the first organic film 131 and the second organic film 133 constitute an organic film 130. Thus, a thickness of the organic film 130 on the metal film 110 becomes thicker than the case where only the first organic film 131 is formed.

Conversely, the reactivity of the first target film 142 (Alo film) formed on the first insulating film 120 is lowered so that adsorption of the reactive functional groups 133b thereon is inhibited. Thus, the second organic film 133 is selectively formed on the first organic film 131, specifically, the metal film 110.

At step S106, the controller 9 determines whether or not the cycle is repeated until the thickness of the organic film 130 reaches a desired thickness. In the case where the cycle has not been repeated until the thickness reaches the desired film thickness (S106, NO), the controller 9 is configured to repeat the processes of S104 and S105. Once the thickness reaches the desired film thickness (S106, YES), the controller 9 is configured to proceed with step S107.

Thus, as illustrated in below-described FIG. 5G, the organic film 130 having the desired thickness can be formed on the metal film 110. Moreover, the thickness of the organic film 130 can be increased to be larger than a thickness of a below-described second insulating film 140.

The process of step S107 will further explained with reference to FIG. 4. At step S107 (S301), the controller 9 is configured to supply a precursor of a second insulating film 140. Here, a trimethyl aluminum (TMA) gas is supplied as the precursor gas of the second insulating film 140. Thus, TMA is adsorbed on a surface of the first insulating film 120 (first target film 142), thereby forming an adsorption layer.

Next, at step S107 (S302), the controller 9 is configured to supply a reaction gas that reacts with the precursor of the second insulating film 140. Here, a H₂O gas is supplied as the reaction gas for the second insulating film 140. Thus, as illustrated in FIG. 5G, TMA adsorbed on the surface of the first insulating film 120 is reacted to form a second target film. The first target film 142 and the second target film constitute a second insulating film 140.

Next, at step S107 (S303), the controller 9 determines whether or not a cycle is repeated a set number of times, where the cycle includes the processes of step S301 and step S302. In the case where the cycle has not been repeated the set number of times (S303, NO), the controller 9 is configured to return the process back to step S301. In the case where the cycle has been repeated the set number of times (S303, YES), the controller 9 is configured to end the process of step S107, and to proceed with step S108 (see FIG. 2).

As illustrated in FIG. 4, when determining that the process of supplying the precursor of the second insulating film 140 (S301) and the process of supplying the reaction gas for the second insulating film 140 (S302) as a cycle, the ALD cycle is repeated two or more times (S303). Thus, the second insulating film 140 is formed on the first insulating film 120.

Moreover, when the second insulating film 140 is formed at step S107, it is important to sufficiently oxidize the second insulating film 140 to form a high quality film. To this end, duration for supplying the reaction gas in the process of supplying the reaction gas (S302) can be adjusted to be longer than, for example, the duration of supplying the reaction gas in the process of supplying the reaction gas (S202) in the formation of the adsorption layer 132.

Thus, as illustrated in FIG. 5G, the second insulating film 140 (AlO film) having a desired thickness can be formed. Moreover, the organic film 130 is formed to have a thickness that is greater than the thickness of the second insulating film 140.

At step S108, the controller 9 is configured to perform etching to remove the organic film 130. Thus, as illustrated in FIG. 5H, the organic film 130 is removed.

At step S109, the controller 9 is configured to form a metal film 150. Thus, as illustrated in FIG. 5I, the metal film 150 is formed on the metal film 110.

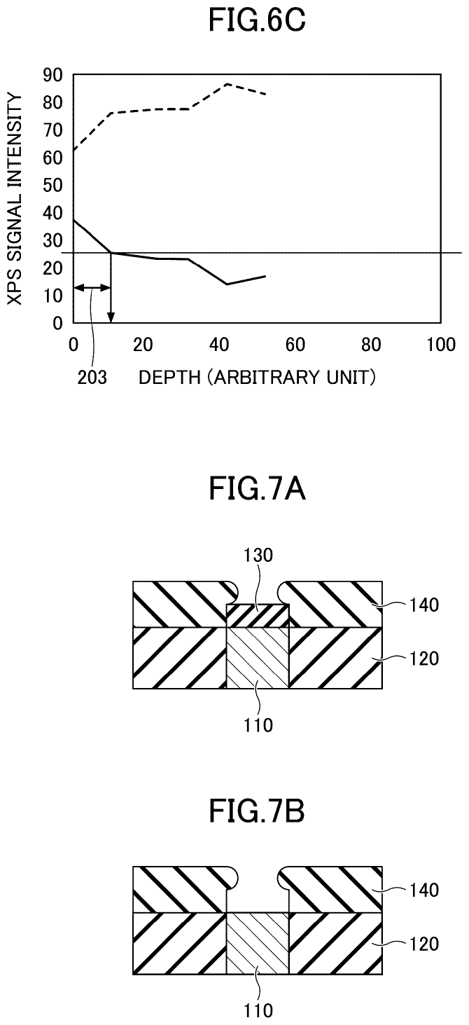

Next, a thickness of the organic film 130 will be explained with reference to FIGS. 6A to 6C. Each of FIGS. 6A to 6C is one example of a graph explaining the thickness of the organic film 130.

In FIG. 6A, PFBA (C₄HF₇O₂) serving as the organic film is supplied on a Ru film serving as the metal film, thereby forming a self-assembled monolayer (SAM), and XPS is performed to analyze F (indicated with a solid line) in the organic film and Ru (indicated with a dashed line) in the metal film. The horizontal axis represents a film thickness direction (depth direction: arbitrary unit), and the vertical axis represents the XPS signal intensity. The thickness of the organic film determined by the XPS is indicated with the arrow 201.

In FIG. 6B, step S103 and two or more cycles of step S104 and S105 are performed by supplying PFBA (C₄HF₇O₂) serving as the organic film on a Ru film serving as the metal film, thereby forming a self-assembled monolayer (SAM), and XPS is performed to analyze F (indicated with a solid line) in the organic film and Ru (indicated with a dashed line) in the metal film. The horizontal axis represents a film thickness direction (depth direction: arbitrary unit), and the vertical axis represents the XPS signal intensity. The thickness of the organic film determined by the XPS is indicated with the arrow 202.

As demonstrated by comparing FIG. 6A and FIG. 6B, the substrate processing method according to the present embodiment can increase the thickness of the organic film formed on the metal film

In FIG. 6C, step S103 and two or more cycles of step S104 and S105 are performed by supplying PFBA (C₄HF₇O₂) serving as the organic film on a SiO₂ film serving as the insulating film, thereby forming a self-assembled monolayer (SAM), and XPS is performed to analyze F (indicated with a solid line) in the organic film and Ru (indicated with a dashed line) in the metal film. The horizontal axis represents a film thickness direction (depth direction: arbitrary unit), and the vertical axis represents the XPS signal intensity. The thickness of the organic film determined by the XPS is indicated with the arrow 203.

As demonstrated by comparing FIG. 6B and FIG. 6C, the substrate processing method according to the present embodiment can selectively form the organic film on the metal film rather than the insulating film. Moreover, the thickness of the organic film can be increased.

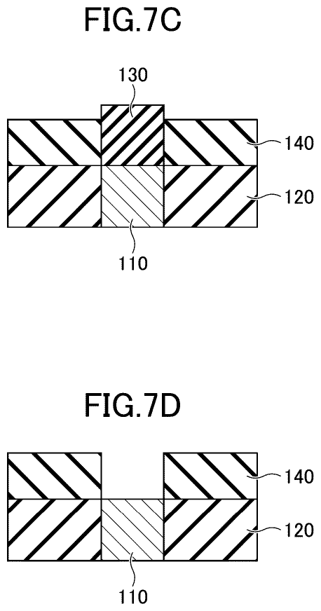

Next, the substrate processing method of the present embodiment will be explained in comparison with a substrate processing method of a referential example with reference to FIGS. 7A to 7D. FIGS. 7A to 7D are one example of diagrams explaining the substrate processing method of the present embodiment in comparison with the substrate processing method of the referential example.

FIG. 7A is a diagram explaining formation of a second insulating film 140 according to the referential example. In the referential example, a thickness of an organic film 130 depends on a length of a straight chain of each organic molecule. As the thickness of the second insulating film 140 is increased, the second insulating film 140 is stuck out over the metal film 110. Therefore, an opening width of an upper side of a recess, such as a hole or the like, becomes narrow after removing the organic film 130, as illustrated in FIG. 7B. When the recess is filled with a metal film 150, a filling defect may be caused.

FIG. 7C is a diagram explaining formation of the second insulating film 140 according to the present embodiment. In the present embodiment, a thickness of the organic film 130 can be increased. Therefore, narrowing of an opening width at an upper side of a recess, such as a hole, can be inhibited after the organic film 130 is removed, as illustrated in FIG. 7D. Thus, when the recess is filled with a metal film 150, a filling defect may be caused.

The disclosed embodiments are explanatory and are not restrictive in every aspect. The above embodiments may be omitted, substituted, or changed in various manner without departing from the scope and spirit of the accompanying claims.

The present application claims priority to Japanese Patent Application No. 2022-19518, filed with the Japan Patent Office on Feb. 10, 2022, the entire contents of which are incorporated in the present application by reference.

### REFERENCE SIGNS LIST

W wafer
9 controller
110 metal film
111 native oxide film
120 first insulating film
130 organic film
131 first organic film
131a straight chain
131b reactive functional group
132 AlF group (adsorption layer)
132 adsorption layer
133 second organic film
133a straight chain
133b reactive functional group
140 second insulating film
141 adsorption layer
142 first target film
150 metal film

1. A substrate processing method, comprising:
a) forming a first organic film on a first material layer of a substrate, the substrate including the first material layer and a second material layer different from the first material layer;
b) supplying a process gas including a raw material of a target film to form a first target film on the second material layer, and to allow an outermost surface of the first organic film to react with process gas to form an adsorption layer;
c) forming a second organic film on the adsorption layer; and
d) forming a second target film on the first target film.

2. The substrate processing method according to claim 1,
wherein a raw material gas of the first organic film includes, in each molecule, a functional group and a straight chain including carbon and halogen, the functional group being selectively adsorbed on the first material layer rather than the second material layer.

3. The substrate processing method according to claim 2,
wherein the functional group of the raw material gas of the first organic film includes thiol, carboxylic acid, or silane coupling.

4. The substrate processing method according to claim 1,
wherein a raw material gas of the second organic film includes, in each molecule, a functional group and a straight chain including carbon and halogen, the functional group being selectively adsorbed on the adsorption layer rather than the second target film.

5. The substrate processing method according to claim 4,
wherein the functional group of the raw material gas of the second organic film is carboxylic acid.

6. The substrate processing method according to claim 1,
wherein the process gas including the raw material of the target film includes a raw material gas and a reaction gas that reacts with the raw material gas.

7. The substrate processing method according to claim 6,
wherein
the raw material gas is TMA, and
the reaction gas is H₂O.

8. The substrate processing method according to claim 1,
wherein
b) and c) are repeated two or more times.

9. The substrate processing method according to claim 6,
wherein b) includes repeating supply of the raw material gas and supply of the reaction gas in an alternating manner.

10. The substrate processing method according to claim 1,
wherein the first material layer is a metal, and the second material layer is a dielectric.

11. The substrate processing method according to claim 1,
wherein the first material layer is a dielectric, and the second material layer is a metal.
